(19) United States
(12) Patent Application Publication
(10) Pub. No.: US 2012/0145848 A1
(43) Pub. Date: Jun. 14, 2012

(54) PIER CAP CLEAT

(76) Inventors: David Schuff, Phoenix, AZ (US); Tracy Metzger, Phoenix, AZ (US)

(21) Appl. No.: 12/965,519

(22) Filed: Dec. 10, 2010

(51) Int. Cl. H01L 23/12; B23P 11/00; F16M 13/02

(52) U.S. Cl. 248/219.2; 248/205.1; 29/428

(57) ABSTRACT

A pier cap comprises a support rail engaging surface and a mounting cleat disposed on the support rail engaging surface. The mounting cleat comprises a substantially round-shaped section coupled to the support rail engaging surface and a substantially wedge-shaped prong section elevated above the support rail engaging surface. A notched section of the mounting cleat defines a space between the support rail engaging surface and the substantially wedge-shaped prong section. The notched section is configured to receive a mounting flange coupled to a support rail of a support structure for a solar panel array.

### FIELD OF INVENTION

The present invention relates to a pier cap for use with a support post, and more particularly, to a pier cap with a mounting cleat for coupling a solar panel support structure to the pier cap, including systems and methods for manufacturing and assembly relating to the same.

### BACKGROUND OF THE INVENTION

Solar energy is typically harvested using an array of photovoltaic panels which collect solar energy and convert it to electricity. Solar arrays often consist of a large number of panels located in proximity to one another. The individual panels are often secured to structures that support a number of panels at once.

Conventional solar panel array support structures often include posts, to which the support structure is secured. The individual solar panels may be mounted to the support structure, which is then secured to the mounting posts. The support structure is often bolted to a number of mounting posts at a number of locations. For example, pier caps may be coupled to the mounting posts, and the support structure may then be bolted to the pier caps.

The assembly of the support structure generally requires a high degree of precision, and as a result, may be labor intensive. Furthermore, the large number of bolts or other fasteners utilized to secure the support structure to the mounting posts and/or pier caps substantially increases the cost of the support structure and associated solar panel system. In addition, the individual panels of the solar array may require maintenance, which may entail at least a partial disassembly of the support structure, for example, by removing a number of bolts from the mounting posts and/or pier caps. As a result, both installation and maintenance of the array may be costly and time consuming.

The complexity of existing solar panel support structures, and the tedious and difficult nature of their assembly, may be seen, for example, by referring to Cusson, U.S. Patent Application Publication No. 2010/0237028. FIGS. 1 and 2 herein illustrate an existing solar panel support structure as described in Cusson. As illustrated in FIG. 1, each location labeled with “40” is a location where a bolt 40 or other fastener is utilized to secure Cusson's support structure 10 to a bracket mount 16 or to another portion of the support structure. FIG. 2 illustrates the complex configuration of Cusson's support structure 10 and the complex nature of the assembly with bolts 40. In the existing support structure illustrated in FIGS. 1 and 2, it appears that approximately 56 bolts or other fasteners are utilized, resulting in complex, time consuming, and costly assembly and maintenance of Cusson's system.

Therefore, a need exists for a support structure for solar panels that allows for quicker and less expensive coupling to pier caps, mounting posts and/or other structural or support devices. Further, a need exists to reduce installation and maintenance times and the associated labor and material costs for such solar panel support structures.

### SUMMARY OF THE INVENTION

In accordance with various embodiments, a support structure for a solar panel array comprises a support rail, such as a hat channel, that comprises a mounting flange. A pier cap may be made of light gage steel, and comprises a mounting cleat that is configured to slidably engage with the mounting flange. A post may be coupled to the pier cap to facilitate providing support to the solar panel array. In an embodiment, the support structure comprises a second support rail with a second mounting flange, and the pier cap further comprises a second mounting cleat configured to slidably engage with the second mounting flange. Additionally, in an embodiment, the pier cap comprises a substantially c-shaped channel configuration.

Further, the pier cap may comprise a hold down mechanism positioned proximate the support rail to facilitate securing the support rail to the pier cap. In this manner, the hold down mechanism may engage the support rail in response to the mounting flange being slidably engaged with the mounting cleat. In an embodiment, the mounting flange is configured to slidably engage with the mounting cleat without using a fastener to couple the mounting flange to the mounting cleat.

According to various embodiments, a method for manufacturing a pier cap comprises forming a material into a channel shaped member during a forming process. During the forming process, a mounting cleat shape may be perforated into the channel shaped member, and the mounting cleat shape may be formed to create a mounting cleat. The mounting cleat forms a space and/or a notch between the mounting cleat and the pier cap, such that the mounting cleat may receive a mounting flange associated with a mounting rail. The mounting cleat shape may be formed into the mounting cleat during the forming process. In an embodiment, the mounting cleat shape may be formed into the mounting cleat during a second forming process. Forming processes as disclosed herein may be any forming process suitable to creating the described components, such as roll forming or press brake forming. Further, in an embodiment, the mounting cleat may be attached to the pier cap after the pier cap has been formed.

Additionally, a method of installing a support structure for a solar panel array, in accordance with various embodiments, comprises securing a pier cap to a support post. A mounting flange on a support rail is aligned with a mounting cleat on the pier cap, such that the support rail provides support to the solar panel array. The method further comprises engaging the mounting flange with the mounting cleat to facilitate engaging the support rail with the pier cap. In an embodiment, a hold down mechanism is disposed proximate the support rail to facilitate preventing the mounting cleat from disengaging with the mounting flange, where a fastener is not utilized to secure the mounting cleat to the mounting flange. In an embodiment, the method further comprises aligning a second mounting flange on a second support rail with a second mounting cleat on the pier cap. The second mounting flange engages the second mounting cleat to facilitate engaging the second support rail with the pier cap.

Moreover, according to various embodiments, a pier cap comprise a support rail engaging surface and a mounting cleat disposed on the support rail engaging surface. The mounting cleat comprises a substantially round-shaped section coupled to the support rail engaging surface and a substantially wedge-shaped prong section elevated above the support rail engaging surface. A notched section of the mounting cleat defines a space between the support rail engaging surface and the substantially wedge-shaped prong section. The notched section is configured to receive a mounting flange coupled to a support rail of a support structure. In an embodiment, the mounting cleat is configured to be at least partially formed during a forming process of the pier cap. Further, in an embodiment, the mounting cleat is configured to be affixed to the pier cap after the pier cap has been formed.

### BRIEF DESCRIPTION OF THE DRAWINGS

The drawings described herein are for illustration purposes only and are not intended to limit the scope of the present disclosure in any way. The present disclosure will become more fully understood from the detailed description and the accompanying drawings herein:

FIG. 1 illustrates an existing support structure for a solar panel system showing an extensive number of bolts;

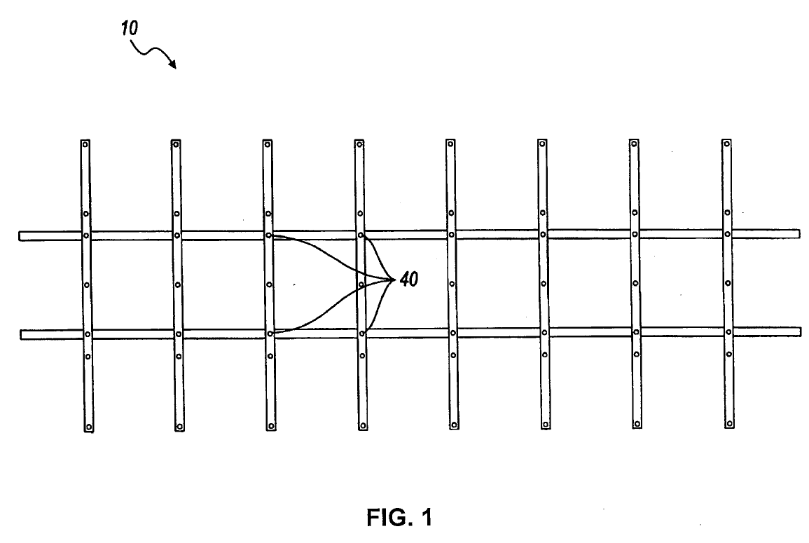

FIG. 2 illustrates a partial view of the existing support structure of FIG. 1;

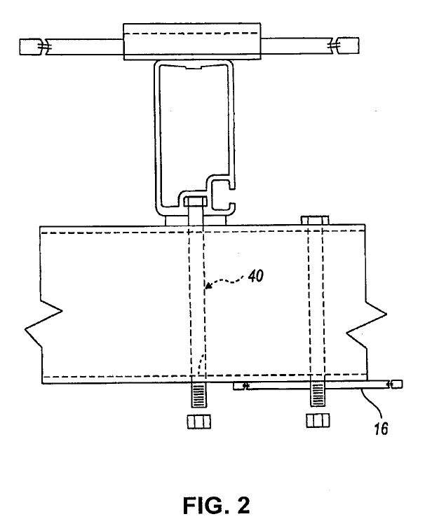

FIG. 3 illustrates a perspective view of a solar panel array with support posts in accordance with an embodiment;

FIG. 4 illustrates a side sectional view of a solar panel array with a pier cap and mounting rails in accordance with an embodiment;

FIG. 5 illustrates an exploded side sectional view of a support rail with a mounting flange proximate a mounting cleat in a pier cap in accordance with an embodiment;

FIG. 6 illustrates top, side, and front views of a pier cap in accordance with an embodiment;

FIG. 7 illustrates a partial front view of a pier cap with a mounting cleat coupled to a support rail surface of the pier cap in accordance with an embodiment;

FIG. 8 illustrates a side view of a mounting cleat in accordance with an embodiment;

FIG. 9 illustrates a top view of a mounting cleat coupled to a pier cap in accordance with an embodiment; and

FIG. 10 illustrates a partial perspective view of a pier cap proximate a support rail with a hold down mechanism coupled to the pier cap and the support rail in accordance with an embodiment.

### DETAILED DESCRIPTION

The detailed description of various embodiments herein makes reference to the accompanying drawing figures, which show various embodiments and implementations thereof by way of illustration and best mode, and not of limitation. While these embodiments are described in sufficient detail to enable those skilled in the art to practice the embodiments, it should be understood that other embodiments may be realized and that mechanical and other changes may be made without departing from the spirit and scope of the present disclosure. Also, any reference to attached, fixed, connected or the like may include permanent, removable, temporary, partial, full and/or any other possible attachment option.

The various embodiments of a support structure comprise the features hereinafter described and particularly pointed out in the claims. The following description and the annexed drawings set forth in detail and demonstrate certain illustrative embodiments of the disclosure. However, these embodiments are indicative of but a few of the various ways in which the principles disclosed herein may be employed. Other objects, advantages and novel features will become apparent from the following detailed description when considered in conjunction with the drawings.

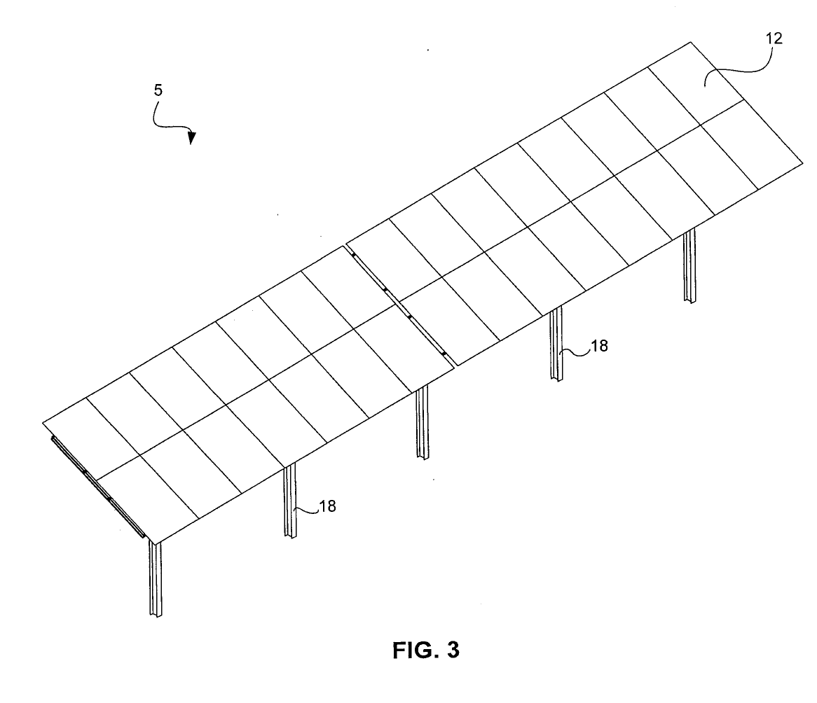

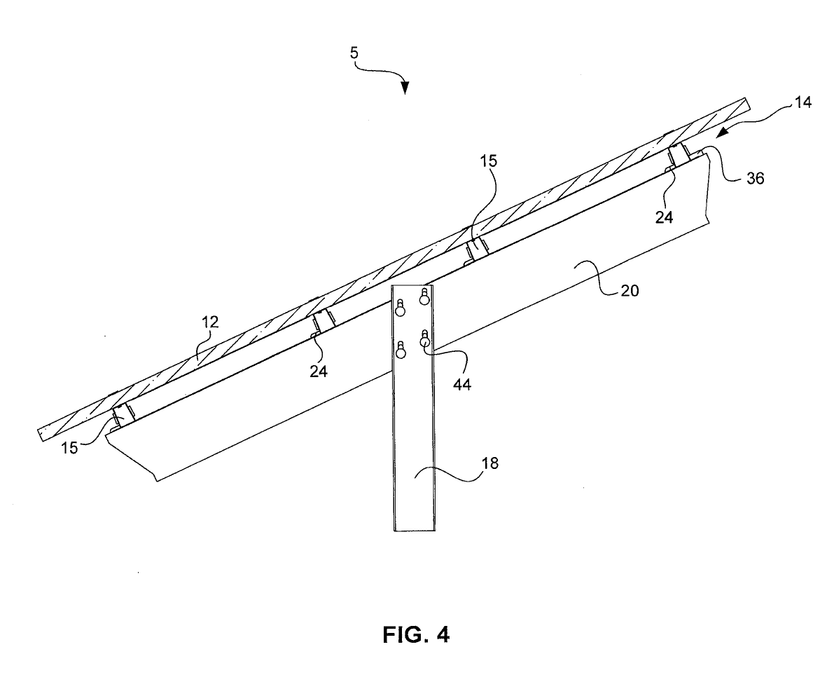

To assist in understanding the context of the present disclosure, a solar panel array configured to utilize a support structure in accordance with various embodiments is illustrated in FIGS. 3 and 4. A solar panel array 5 includes a number of solar panels 12 that are attached or otherwise coupled to a panel mounting structure 14. For example, panel mounting structure 14 may comprise support rails 15 that facilitate securing solar panels 12 to panel mounting structure 14. In an embodiment, support rails 15 comprise hat channels. Panel mounting structure 14 and/or rails 15 may be coupled to pier caps 20, as disclosed below, and pier caps 20 may be arranged in a substantially parallel fashion to each other. Pier caps 20 are coupled to support posts 18 that are secured in a substrate, such as the ground, cement, concrete, or other supportive material, to provide support to solar panel array 5. Any post 18 and/or any substrate that provides adequate support for solar panel array 5 is contemplated within the scope of the present disclosure.

Referring to FIG. 4, and in accordance with various embodiments, a support structure, such as panel mounting structure 14 comprises support rail 15 or a plurality of support rails 15. Support rails 15 attach and provide support to a number of solar panels 12. Support rail 15 may comprise a rectangular tubular member. Further, in an embodiment, support rail 15 may comprise a circular tubular member. However, a support member of any geometry that is capable of providing support to solar panels 12 is contemplated within the scope of the present disclosure. As illustrated in FIG. 4, according to an embodiment, four support rails 15 may be utilized to form panel mounting structure 14 to provide support to solar panels 12, but more or fewer support rails 15 may be used in various embodiments. For example, in an embodiment, a range of one to three support rails 15 may be used to provide sufficient support to solar panels 12. In another embodiment, a range of four to seven support rails 15 may be utilized, and in yet another embodiment, eight or more support rails 15 may be utilized.

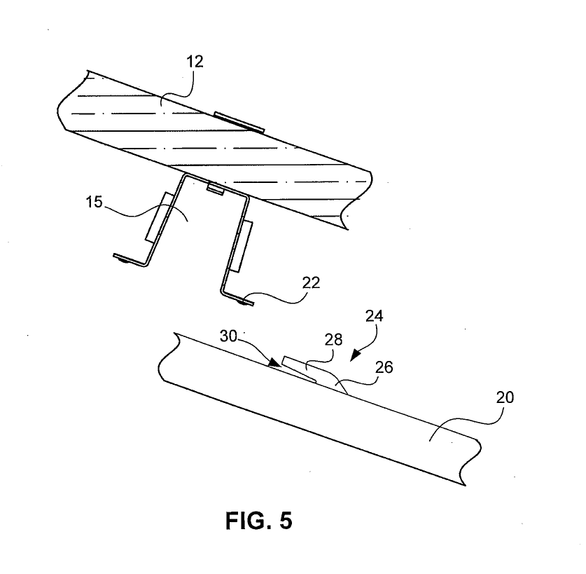

In accordance with further embodiments, and with reference to FIG. 5, support rail 15 may comprise a mounting flange 22 to facilitate securing support rail 15 to pier cap 20. Mounting flanges 22 may comprise a flange, a lip, a tab, and the like that extends from support rail 15 and is substantially parallel to the absorbing surface of solar panel 12. In this manner, mounting flange 22 is configured to interface and/or nest with a mounting cleat 24 on pier cap 20, as discussed further below, to facilitate securing support rail 15 to pier cap 20. It should be understood that any flange or device that allows support rail 15 to engage with mounting cleat 24 on pier cap 20 is contemplated within the scope of the present disclosure. Furthermore, mounting flanges 22 may be oriented in any configuration, substantially parallel to solar panel 12 or otherwise, that advantageously allows mounting flanges 22 to engage with mounting cleats 24.

In an embodiment, each support rail 15 has a sufficient number of mounting flanges 22 to interface with the corresponding number of pier caps 20 and mounting cleats 24 with which the mounting flanges 22 interface. For example, each support rail 15 may comprise a plurality of flanges 22 to facilitate coupling support rail 15 to a plurality of pier caps 20. Further, in an embodiment, each support rail 15 may comprise a substantially continuous flange 22 running along the length of support rail 15 to facilitate coupling to mounting cleats 24 on pier caps 20.

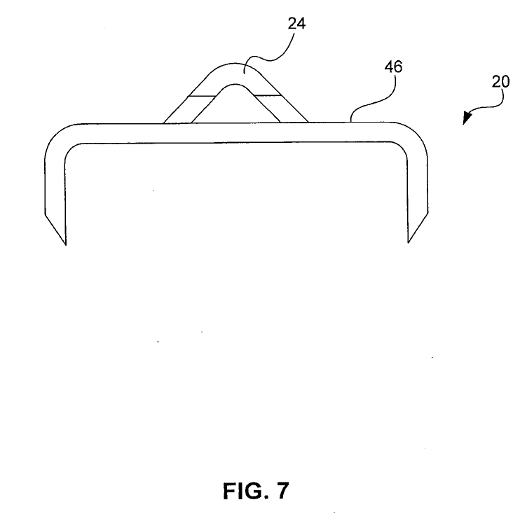

Referring to FIGS. 4, 6 and 7, and according to various embodiments, pier cap 20 comprises a channeled member that is open on one side. The side opposite the open side contains bolt notches 42 configured to receive bolts 44 to secure pier cap 20 to support post 18. In this manner, bolt notches 42 are configured to allow solar panels 12 to be properly oriented when pier cap 20 receives panel support structure 14. In an embodiment, pier cap 20 is a substantially rectangular member. Further, in an embodiment, pier cap 20 is a substantially c-shaped member. Pier cap 20 may comprise stainless steel, steel, iron, or any other suitable metal, metal alloy, composite material, and the like, that is configured to provide sufficient support to panel mounting structure 14 and/or solar panels 12.

Various numbers of pier caps 20, mounting cleats 24, support rails 15, and mounting flanges 22 are contemplated in accordance with embodiments of the present disclosure. For example, each pier cap 20 may comprise four mounting cleats 24 configured to interface with four mounting flanges 22 on four support rails 15. Further, depending on the dimensions of solar panel array 5, more or fewer mounting cleats 24, support rails 15, and/or mounting flanges 22 may be employed. In an embodiment, a range of one to four mounting cleats 24 on each pier cap 20 may be utilized. Further, in an embodiment, a range of five to ten mounting cleats 24 on each pier cap 20 may be utilized. In another embodiment, ten or more mounting cleats 24 on each pier cap may be utilized to allow mounting structure 14 to be secured to pier caps 20.

Additionally, a number of pier caps 20 may be advantageously utilized to provide sufficient support to the structure that is mounted to pier caps 20. For example, with reference to FIGS. 3 and 4, in an embodiment, five mounting posts 18 and five associated pier caps 20 may be utilized to provide sufficient support to solar panel array 5. In another embodiment, a range of one to four mounting posts 18 and associated pier caps 20 may be utilized, and in yet another embodiment, six or more mounting posts 18 and associated pier caps 20 may be utilized. It should be understood that other applications for pier caps 20 and/or mounting cleats 24 may result in different numbers of pier caps 20, mounting cleats 24, support rails 15, and/or mounting flanges 22, than those numbers and ranges disclosed herein, and all such variations and applications are contemplated within the scope of the present disclosure.

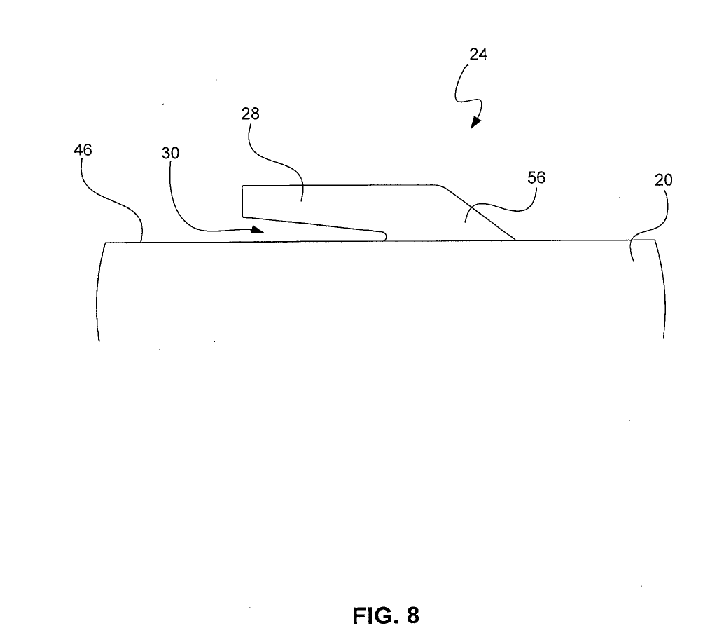

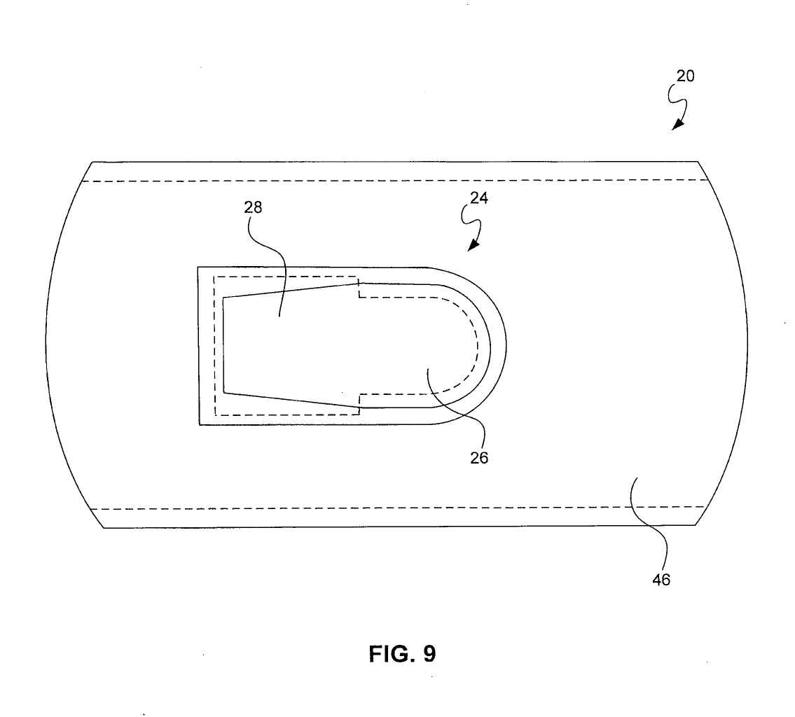

Referring to FIGS. 8 and 9, mounting cleat 24 will now be described in more detail in accordance with various embodiments. A portion of mounting cleat 24 may be elevated from a top and/or mounting surface 46 of pier cap 20. Surface 46 is referred to as a “mounting” surface because support rail 15 couples and/or mounts proximate surface 46. For example, a wedge shaped prong 28 of mounting cleat 24 may be elevated from surface 46 to allow mounting flanges 22 to securely nest within a space 30 formed between surface 46 and wedge shaped prong 28 of mounting cleat 24. Further, in an embodiment, mounting cleat 24 may comprise a round shaped rear section 56 that couples wedge shaped prong 28 to mounting surface 46 of pier cap 20. It should be noted that mounting cleat 24 may have other geometries that facilitate securely receiving mounting flange 22 without departing from the scope of the present disclosure. Further, in an embodiment, pier cap 20 may comprise at least two mounting cleats 24 to facilitate coupling at least two support rails 15 to pier cap 20.

With reference again to FIGS. 4 and 5, and in accordance with an embodiment, each pier cap 20 may be configured to receive four support rails 15. These support rails 15 each comprise a mounting flange 22 that is configured to interface with a corresponding mounting cleat 24 on pier cap 20. Where panel mounting structure 14 comprises four support rails 15, rails 15 may accordingly be slid into place onto the pier cap 20 and mounting post 18 assemblies by sliding mounting flanges 22 into spaces 30 of mounting cleats 24. In this manner, bolts or other fasteners are not required to secure individual support rails 15 to pier caps 20, resulting in a substantial savings in material and labor cost (e.g., compared to where U-bolts or other fasteners are used to secure the individual support rails 15). However, in various embodiments, some fastening mechanisms may be advantageously used at certain locations to facilitate securing mounting structure 14 to pier caps 20 and/or to secure other components of solar panel array 5.

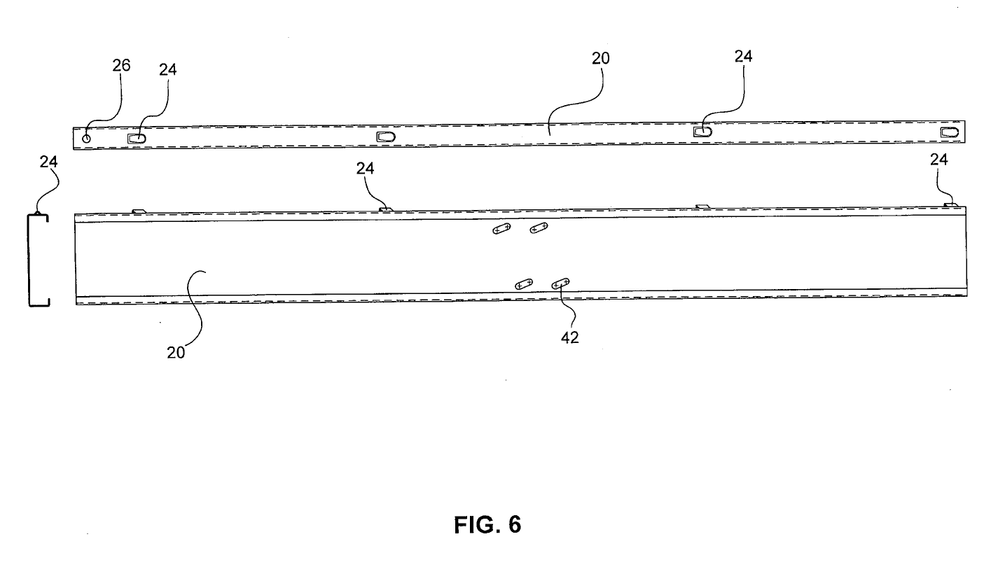

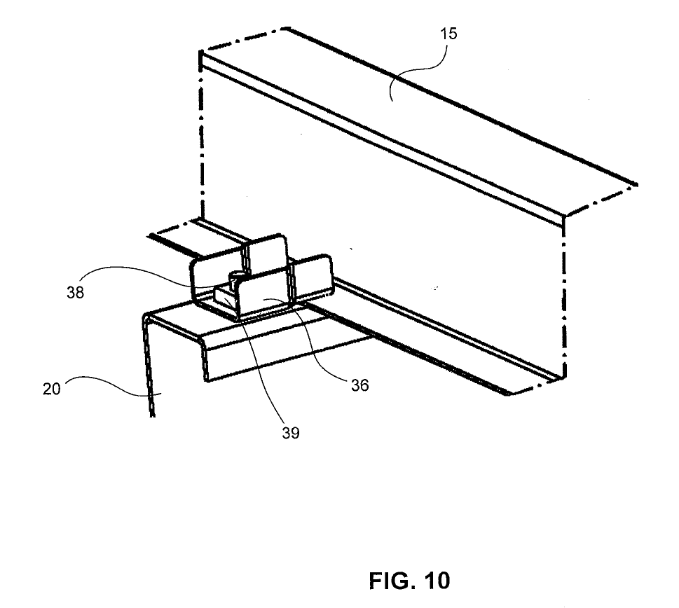

With reference again to FIGS. 4 and 6, and with reference also to FIG. 10, in various embodiments, once mounting flanges 22 have been coupled to mounting cleats 24, pier cap 20 may comprise a hold down mechanism to facilitate securing panel mounting structure 14 to pier cap 20. For example, the hold down mechanism may be positioned proximate a flange of support rail 15 to facilitate securing support rail 15 to pier cap 20. In various embodiments, one hold down mechanism may be utilized for each pier cap 20 to facilitate securing support structure 14 and/or support rail 15 to pier cap 20.

The hold down mechanism may comprise any clamp, clip, fastener, or other structure or mechanism configured to facilitate securing support structure 14 and/or support rail 15 to pier cap 20. In a preferred embodiment, the hold down mechanism may comprise a hold down clip 36 that is secured to pier cap 20 and support rail 15 with a bolt 38. Bolt 38 may be configured to pass through a bolt hole 26 in pier cap 20 to facilitate securing panel mounting structure 14 and/or support rail 15 to pier cap 20. With specific reference to FIG. 10, hold down clip 36 may be positioned over a flange of support rail 15, and bolt 38 may pass through bolt hole 26 in pier cap 20 to facilitate securing hold down clip 36 and support rail 15 to pier cap 20.

A nut 39 or other fastener may be used to appropriately secure bolt 38 to hold down clip 36. In an embodiment, nut 39 may be stamped or otherwise formed into hold down clip 36. In other embodiments, nut 39 may be a separate component from hold down clip 36. It should be understood that other mechanisms, adhesives, or devices may be utilized to appropriately secure mounting structure 14 to pier cap 20 with or without utilizing bolt hole 26, bolt 38, and/or hold down clip 36, without departing from the scope of the present disclosure.

In various embodiments, one hold down mechanism may be utilized to secure panel mounting structure 14 and/or support rail 15 into pier cap 20, and this one hold down mechanism may sufficiently restrict motion of all support rails 15 and/or mounting flanges 22 with respect to each pier cap 20. In this regard, mounting flanges 22 may not substantially disengage with mounting cleats 24 while the hold down mechanism is in place with respect to support rail 15. In other embodiments, other fasteners may be utilized to secure panel mounting structure 14 to pier caps 20 without using a similar number of fasteners that would be utilized without mounting cleats 24. Further, in certain applications, adhesives, welds, fasteners and/or other devices may be utilized to enhance and/or complement the functionality of cleats 24 and/or the hold down mechanism in securing and providing support to mounting structure 14 and/or other components of solar panel array 5. Accordingly, the use of cleats 24 and/or the hold down mechanism does not necessarily preclude the use of other fasteners.

Various forming processes may be utilized to form the components of pier cap 20 in accordance with embodiments of the present disclosure. For example, pier cap 20 may be created by a metal forming process, and may be formed into a substantially C-shaped channel, into an angle shape, or into other configurations that provide support to mounting structure 14 and/or solar panels 12. In an embodiment, pier cap 20 is formed with a press brake from a sheet of suitable material (such as light gage steel) that has been cut to a suitable size. In another embodiment, pier cap 20 may be roll formed from a sheet of suitable material that has been cut to a suitable size. Any method of forming pier cap 20 which results in a pier cap 20 having characteristics as disclosed herein is contemplated within the scope of the present disclosure.

In various embodiments, mounting cleat 24 may be fabricated concurrently with the forming of pier cap 20. The shape of mounting cleat 24 may be perforated in pier cap 20 during the forming of pier cap 20. Mounting cleat 24 may then be formed to create round shaped rear section 56 coupled to wedge shaped prong 28 in order to form space 30. Such forming may occur during or after the forming of pier cap 20. For example, mounting cleat 24 may be both perforated and formed, creating space 30, during a press brake and/or roll forming process. However, mounting cleat 24 may be formed and/or affixed to pier cap 20 after pier cap 20 has been formed. For example, mounting cleat 24 may be perforated and formed after forming pier cap 20. In an embodiment, mounting cleat 24 may be separately formed and then affixed (e.g., by welding or other adhesion mechanism) to pier cap 20 after pier cap 20 has been formed. Furthermore, it should be understood that any method of forming mounting cleat 24 and affixing it to pier cap 20 to facilitate securing mounting flanges 22 of support rails 15 to pier cap 20 is contemplated within the scope of the present disclosure.

Thus, support structures according to embodiments of the present disclosure facilitate simpler, more efficient, and less expensive installation, removal and/or repair of the support structures. Where such support structures allow for reduced assembly components and labor costs (e.g., where fewer bolts or other fasteners may be utilized), solar panels and other devices that utilize these support structures may be provided and maintained at a reduced cost.

Although this disclosure has been described with respect to certain embodiments, equivalents and modifications will occur to others who are skilled in the art upon reading and understanding of the specification. Various embodiments include all such equivalents and modifications, and are limited only by the scope of the following claims.

Additionally, benefits, other advantages, and solutions to problems have been described herein with regard to various embodiments. However, the benefits, advantages, solutions to problems, and any elements that may cause any benefit, advantage, or solution to occur or become more pronounced are not to be construed as critical, required, or essential features or elements of the inventions. The scope of the disclosure is accordingly to be limited by nothing other than the appended claims, in which reference to an element in the singular is not intended to mean “one and only one” unless explicitly so stated, but rather “one or more.”

1. A support structure for a solar panel array comprising:
a support rail comprising a mounting flange;
a pier cap comprising a mounting cleat configured to slidably engage with the mounting flange; and
a post coupled to the pier cap, wherein the post is configured to provide support to the solar panel array.

2. The support structure of claim 1, further comprising a second support rail comprising a second mounting flange.

3. The support structure of claim 2, wherein the pier cap further comprises a second mounting cleat configured to slidably engage with the second mounting flange.

4. The support structure of claim 1, wherein a solar panel is configured to be attached to the support rail.

5. The support structure of claim 1, further comprising at least two support rails.

6. The support structure of claim 1, wherein the pier cap comprises light gage steel.

7. The support structure of claim 1, wherein the pier cap comprises a substantially c-shaped channel configuration.

8. The support structure of claim 1, further comprising a hold down mechanism.

9. The support structure of claim 8, wherein the pier cap comprises a bolt hole.

10. The support structure of claim 9, further comprising a bolt configured to pass through the bolt hole to engage the hold down mechanism in response to the mounting flange slidably engaging with the mounting cleat.

11. The support structure of claim 1, wherein the mounting flange is configured to slidably engage with the mounting cleat without using a fastener to couple the mounting flange to the mounting cleat.

12. A method for manufacturing a pier cap comprising:
forming a material into a channel shaped member during a forming process; and
during the forming process, perforating a mounting cleat shape into the channel shaped member, wherein the mounting cleat shape is configured to be formed into a mounting cleat to create a space between the mounting cleat and the pier cap.

13. The method of claim 12, further comprising forming the mounting cleat shape into the mounting cleat during the forming process.

14. The method of claim 13, further comprising forming the mounting cleat shape into the mounting cleat during a second forming process.

15. The method of claim 14, wherein the forming process and the second forming process comprise press brake forming.

16. A method of installing a support structure for a solar panel array comprising:
securing a pier cap to a support post;
aligning a mounting flange on a support rail with a mounting cleat on the pier cap, wherein the support rail provides support to the solar panel array; and
engaging the mounting flange with the mounting cleat to facilitate engaging the support rail with the pier cap.

17. The method of claim 16, further comprising:
aligning a bolt hole in the pier cap with a hold down clip proximate the support rail; and
inserting a bolt into the bolt hole to engage the hold down clip to facilitate preventing the mounting cleat from disengaging with the mounting flange, wherein a fastener is not utilized to secure the mounting cleat to the mounting flange.

18. The method of claim 16, further comprising:
aligning a second mounting flange on a second support rail with a second mounting cleat on the pier cap; and
engaging the second mounting flange with the second mounting cleat to facilitate engaging the second support rail with the pier cap.

19. A pier cap comprising:
a support rail engaging surface; and
a mounting cleat disposed on the support rail engaging surface, the mounting cleat comprising;
a substantially round-shaped section coupled to the support rail engaging surface;
a substantially wedge-shaped prong section elevated above the support rail engaging surface; and
a notched section defining a space between the support rail engaging surface and the substantially wedge-shaped prong section, wherein the notched section is configured to receive a mounting flange coupled to a support rail of a support structure.

20. The pier cap of claim 19, wherein the mounting cleat is configured to be at least partially formed during a forming process of the pier cap.

21. The pier cap of claim 19, wherein the mounting cleat is configured to be affixed to the pier cap after the pier cap has been formed.
